(19) United States
(12) Patent Application Publication
(10) Pub. No.: US 2026/0057938 A1
(43) Pub. Date: Feb. 26, 2026

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Hanae ISHIHARA, Yokkaichi Mie (JP)

(21) Appl. No.: 19/040,829

(22) Filed: Jan. 29, 2025

(30) Foreign Application Priority Data
Aug. 21, 2024 (JP) 2024-139659

(51) Int. Cl. G11C 16/04; H10B 43/10; H10B 43/35

(52) U.S. Cl. CPC G11C 16/0483; H10B 43/10; H10B 43/35

(57) ABSTRACT

A semiconductor memory device includes a substrate including a first region and a second region surrounding the first region when viewed from above the substrate, an insulating layer on the substrate, a memory cell array above the first region, a conductor above the second region, that extends through the insulating layer in a first direction perpendicular to the substrate, and a covering layer contacting the conductor in the first direction. The conductor includes a first conductor portion, a first end of which is in contact with the covering layer, and a second conductor portion in contact with a second end of the first conductor portion that is opposite to the first end in the first direction. The first conductor portion includes a first core and a first barrier metal film that covers a side surface of the first core and the second end of the first conductor portion.

### CROSS-REFERENCE TO RELATED APPLICATIONS

This application is based upon and claims the benefit of priority from Japanese Patent Application No. 2024-139659, filed Aug. 21, 2024, the entire contents of which are incorporated herein by reference.

### FIELD

Embodiments described herein relate generally to a semiconductor memory device and a method for manufacturing a semiconductor memory device.

### BACKGROUND

Devices having a plurality of circuits or elements formed therein are bonded to each other to make one semiconductor memory device.

### BRIEF DESCRIPTION OF THE DRAWINGS

FIG. 1 is a block diagram showing a semiconductor memory device according to a first embodiment.

FIG. 2 is a view showing an equivalent circuit of a memory cell array according to the first embodiment.

FIG. 3 is a cross-sectional view of the semiconductor memory device according to the first embodiment.

FIG. 4 is a plan view of the semiconductor memory device according to the first embodiment.

FIG. 5 is a cross-sectional view of the memory cell array according to the first embodiment.

FIG. 6 is a cross-sectional view in the vicinity of a columnar body of the memory cell array according to the first embodiment.

FIG. 7 is another cross-sectional view in the vicinity of the columnar body of the memory cell array according to the first embodiment.

FIG. 8 is a cross-sectional view of the semiconductor memory device according to the first embodiment.

FIG. 9 is a cross-sectional view showing a method for manufacturing the semiconductor memory device according to the first embodiment.

FIG. 10 is a cross-sectional view showing the method for manufacturing the semiconductor memory device according to the first embodiment.

FIG. 11 is a cross-sectional view showing the method for manufacturing the semiconductor memory device according to the first embodiment.

FIG. 12 is a cross-sectional view showing the method for manufacturing the semiconductor memory device according to the first embodiment.

FIG. 13 is a cross-sectional view showing the method for manufacturing the semiconductor memory device according to the first embodiment.

FIG. 14 is a cross-sectional view showing the method for manufacturing the semiconductor memory device according to the first embodiment.

FIG. 15 is a cross-sectional view showing the method for manufacturing the semiconductor memory device according to the first embodiment.

FIG. 16 is a cross-sectional view showing the method for manufacturing the semiconductor memory device according to the first embodiment.

FIG. 17 is a cross-sectional view showing the method for manufacturing the semiconductor memory device according to the first embodiment.

FIG. 18 is a cross-sectional view showing the method for manufacturing the semiconductor memory device according to the first embodiment.

FIG. 19 is a cross-sectional view showing the method for manufacturing the semiconductor memory device according to the first embodiment.

FIG. 20 is a cross-sectional view showing the method for manufacturing the semiconductor memory device according to the first embodiment.

FIG. 21 is a cross-sectional view of a semiconductor memory device according to a second embodiment.

FIG. 22 is a cross-sectional view showing the method for manufacturing the semiconductor memory device according to the second embodiment.

FIG. 23 is a cross-sectional view showing the method for manufacturing the semiconductor memory device according to the second embodiment.

FIG. 24 is a cross-sectional view showing the method for manufacturing the semiconductor memory device according to the second embodiment.

FIG. 25 is a cross-sectional view showing the method for manufacturing the semiconductor memory device according to the second embodiment.

FIG. 26 is a cross-sectional view showing the method for manufacturing the semiconductor memory device according to the second embodiment.

FIG. 27 is a cross-sectional view showing the method for manufacturing the semiconductor memory device according to the second embodiment.

### DETAILED DESCRIPTION

Embodiments provide a semiconductor memory device and a method for manufacturing a semiconductor memory device capable of preventing deterioration in reliability due to damage and water entering.

In general, according to one embodiment, a semiconductor memory device comprises a substrate including a first region and a second region surrounding the first region when viewed from above the substrate; an insulating layer on the substrate; a memory cell array having a plurality of memory cells above the first region; a conductor above the second region, that extends through the insulating layer in a first direction perpendicular to the substrate; and a covering layer in contact with the conductor in the first direction. The conductor includes: a first conductor portion, a first end of which is in contact with the covering layer, and a second conductor portion in contact with a second end of the first conductor portion that is opposite to the first end in the first direction. The first conductor portion includes a first core and a first barrier metal film that covers a side surface of the first core and the second end of the first conductor portion.

Hereinafter, semiconductor memory devices according to embodiments will be described with reference to the drawings. In the following description, configurations having the same or similar functions are designated by the same reference numerals. Then, the duplicate description of those configurations may be omitted. In the present disclosure, the term “connection” is not limited to the case of being physically connected, but also includes the case of being electrically connected.

In the present application, the terms are defined as follows. “Parallel”, “orthogonal”, or “same” may respectively include “substantially parallel”, “substantially orthogonal”, or “substantially the same”. The term “connection” is not limited to mechanical connection and may include electrical connection. That is, the term “connection” is not limited to a case where a plurality of elements are directly connected, and may include a case where a plurality of elements are connected with another element interposed therebetween. “Overlapping” is not limited to a case where a plurality of elements are in contact with each other, and may also include a case where a plurality of elements are separated from each other (i.e., a case where projected images of a plurality of elements overlap each other when viewed in a certain direction).

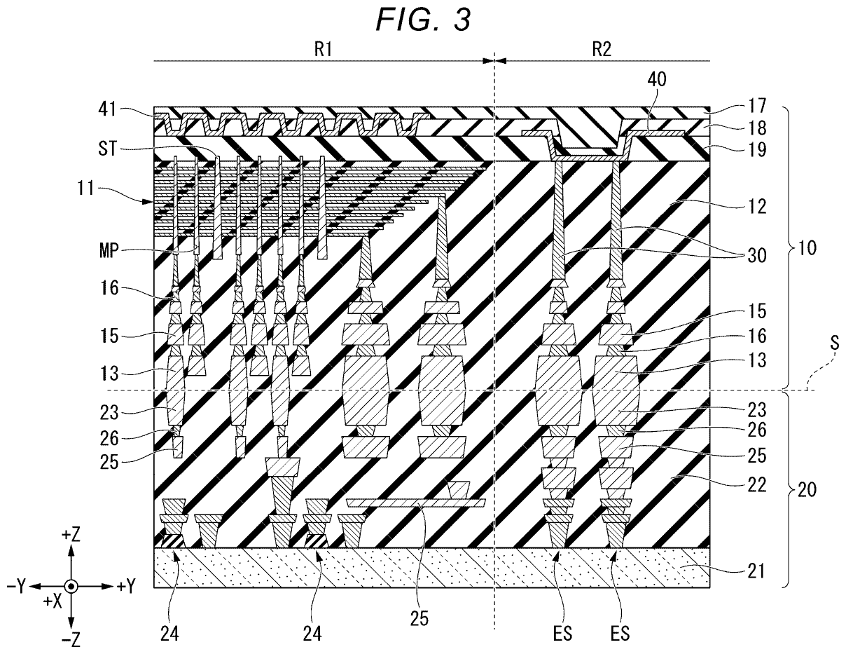

A +X direction, a −X direction, a +Y direction, a −Y direction, a +Z direction, and a −Z direction are defined as follows. The +X direction is a direction in which a word line WL to be described later extends. The −X direction is a direction opposite to the +X direction. When the +X direction and the −X direction are not distinguished from each other, both directions are simply referred to as an “X direction”. The +Y direction is a direction that intersects (for example, is orthogonal to) the X direction. The +Y direction is a direction in which a bit line BL to be described later extends. The −Y direction is a direction opposite to the +Y direction. When the +Y direction and the −Y direction are not distinguished from each other, both directions are simply referred to as a “Y direction”. The +Z direction is a direction that intersects (for example, is orthogonal to) the X direction and the Y direction. The +Z direction is a direction from a first substrate 21 to a memory cell array 11 to be described later (refer to FIG. 3). The −Z direction is a direction opposite to the +Z direction. When the +Z direction and the −Z direction are not distinguished from each other, both directions are simply referred to as a “Z direction”. In the present application, the +Z direction side may be referred to as “upper” and the −Z direction side may be referred to as “lower”. Here, these expressions are for convenience only and do not specify the direction of gravity. In the drawings to be described later, illustrations of configurations not related to the descriptions may be omitted.

### First Embodiment

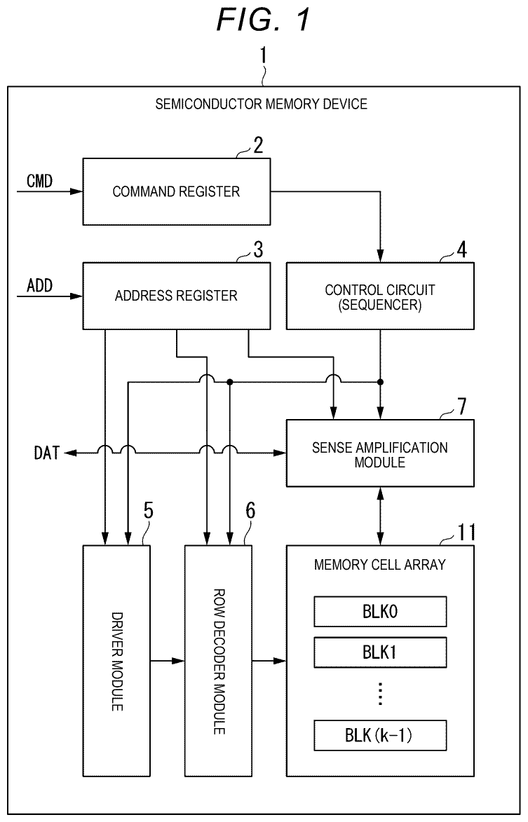

FIG. 1 is a block diagram showing a semiconductor memory device 1. The semiconductor memory device 1 is, for example, a non-volatile semiconductor memory device such as a NAND flash memory. The semiconductor memory device 1 may be connected to, for example, an external host device and used as a memory of the host device. The semiconductor memory device 1 includes, for example, a memory cell array 11, a command register 2, an address register 3, a control circuit 4 (e.g., a sequencer), a driver module 5, a row decoder module 6, and a sense amplification module 7.

The memory cell array 11 includes a plurality of blocks BLK0 to BLK(k-1) where k is an integer of 1 or more. The block BLK is a collection of memory cell transistors. The block BLK is used as, for example, a data erasing unit. The memory cell array 11 is provided with a plurality of bit lines and a plurality of word lines. Each memory cell transistor is associated with one bit line and one word line.

The command register 2 stores a command CMD that the semiconductor memory device 1 receives from a host device. The address register 3 stores address information ADD that the semiconductor memory device 1 receives from the host device. The address information ADD is used to select the blocks BLK, word lines, and bit lines. The control circuit 4 controls various operations of the semiconductor memory device 1. For example, the control circuit 4 executes a data write operation, a read operation, an erasing operation and the like based on the command CMD stored in the command register 2.

The driver module 5 includes a voltage generation circuit and generates voltages used for various operations of the semiconductor memory device 1. The row decoder module 6 applies a voltage that is applied to a signal line corresponding to a word line to be selected, to the word line. The sense amplification module 7 applies a desired voltage to each bit line in a write operation. In a read operation, the sense amplification module 7 determines data stored in each memory cell transistor based on a voltage of each bit line, and transmits the determination result as read data DAT to the host device.

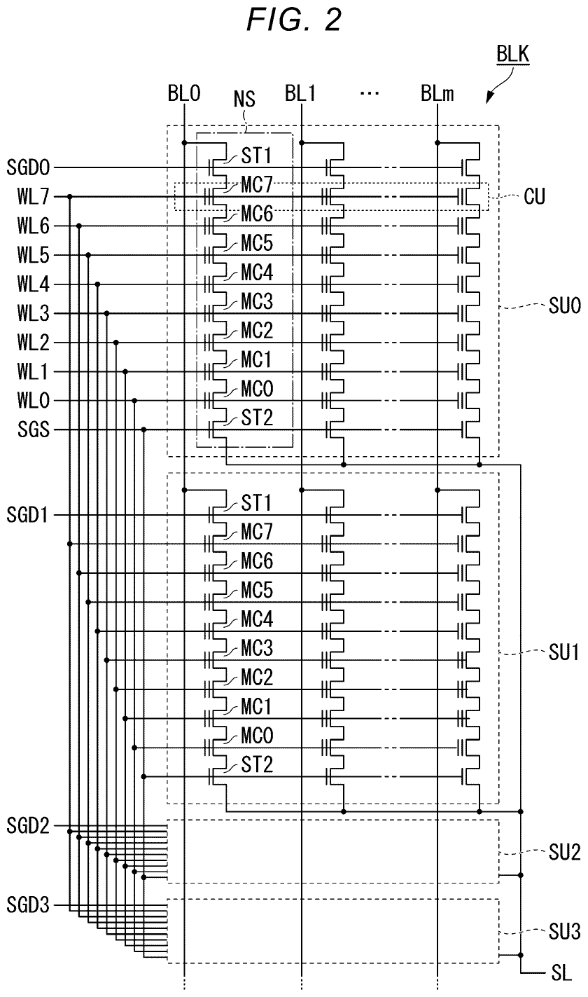

FIG. 2 is a view showing an equivalent circuit of the memory cell array 11. FIG. 2 shows one block BLK provided in the memory cell array 11. The block BLK includes a plurality of strings STR (for example, five strings STR0 to STR4).

Each string STR includes a plurality of NAND strings NS respectively associated with bit lines BL0 to BLm (m is an integer of 1 or more). Each NAND string NS includes a plurality of memory cell transistors MC0 to MCn (n is an integer of 1 or more), one or more drain-side select transistors ST1, and one or more source-side select transistors ST2.

In each NAND string NS, the memory cell transistors MC0 to MCn are connected to each other in series. Each memory cell transistor MC includes a control gate and a charge storage portion. The control gate of the memory cell transistor MC is connected to any one of the word lines WL0 to WLn. In each memory cell transistor MC, charges are accumulated in the charge storage portion according to a voltage applied to the control gate via the word line WL, and the data is stored in a non-volatile manner.

A drain of the drain-side select transistor ST1 is connected to the bit line BL corresponding to the NAND string NS. The source of the drain-side select transistor ST1 is connected to one end of the memory cell transistors MC0 to MCn connected to each other in series. A control gate of the drain-side select transistor ST1 is connected to any of drain-side select gate lines SGD0 to SGD3. The drain-side select transistor ST1 is electrically connected to the row decoder module 6 via the drain-side select gate line SGD. The drain-side select transistor ST1 connects the NAND string NS to the bit line BL when a predetermined voltage is applied to the corresponding drain-side select gate line SGD.

The drain of the source-side select transistor ST2 is connected to the other ends of the memory cell transistors MC0 to MCn connected to each other in series. A source of the source-side select transistor ST2 is connected to a source line SL. A control gate of the source-side select transistor ST2 is connected to a source-side select gate line SGS. The source-side select transistor ST2 connects the NAND string NS to the source line SL when a predetermined voltage is applied to the source-side select gate line SGS.

In the same block BLK, control gates of the memory cell transistors MC0 to MCn are respectively and commonly connected to the corresponding word lines WL0 to WLn. In the same string STR, control gates of the drain-side select transistors ST1 are commonly connected to the corresponding drain-side select gate lines SGD. The control gate of the source-side select transistors ST2 is commonly connected to the source-side select gate line SGS. In the memory cell array 11, the bit line BL is shared by the NAND strings NS to which the same column address is assigned in the plurality of strings STR.

FIG. 3 is a cross-sectional view of the semiconductor memory device 1. The semiconductor memory device 1 includes a memory chip 10 and a circuit chip 20, and the memory chip 10 and the circuit chip 20 are bonded to each other at a bonding surface S. The memory chip 10 includes the memory cell array 11. The circuit chip 20 functions as a control circuit (or a logical circuit) that controls the operation of the memory chip 10. The memory chip 10 and the circuit chip 20 are electrically connected to each other through a second pad 13 and a first pad 23 on the bonding surface S. The semiconductor memory device 1 shown in FIG. 1 is mounted with the memory chip 10 on the circuit chip 20.

The circuit chip 20 includes the first substrate 21, an insulating layer 22, the first pad 23, a transistor 24, a wiring 25, and a via 26.

The first substrate 21 is, for example, a semiconductor substrate made of silicon. The insulating layer 22 is stacked on the first substrate 21. The insulating layer 22 is an interlayer insulating film that insulates between the multilayer wirings. The interlayer insulating film is, for example, an oxide film such as a silicon oxide film.

The first pad 23 is responsible for the electrical connection between the memory chip 10 and the circuit chip 20 on the bonding surface S. The first pad 23 is electrically connected to, for example, the transistor 24. The transistor 24 is formed on the first substrate 21. The transistor 24 is, for example, a part of a CMOS circuit.

The wiring 25 and the via 26 are, for example, conductors such as copper and tungsten. The via 26 provides an electrical connection between the transistor 24 and the wiring 25, between the wiring 25 and the first pad 23, or between the wirings 25.

The memory chip 10 includes the memory cell array 11, an insulating layer 12, the second pad 13, a wiring 15, a via 16, insulating layers 17, 18, and 19, a conductor 30, a covering layer 40, and a conductive layer 41.

The memory cell array 11 is a collection of memory cell transistors. The memory cell array 11 has a plurality of conductive layers, a plurality of insulating layers, a columnar body MP, and a slit ST. The configuration of the memory cell array 11 will be described in detail later.

The insulating layer 12 covers the memory cell array 11. The insulating layer 12 is an interlayer insulating film that insulates between the multilayer wirings. The second pad 13 is responsible for the electrical connection between the memory chip 10 and the circuit chip 20 on the bonding surface S.

The second pad 13 is electrically connected to, for example, the memory cell array 11. The wiring 15 and the via 16 are, for example, conductors such as copper and tungsten. The via 16 is provided between the memory cell array 11 and the wiring 15, and is responsible for the electrical connection between the wiring 15 and the second pad 13 or between the wirings 15. The insulating layers 17, 18, and 19 are, for example, a silicon oxide film and a silicon nitride film.

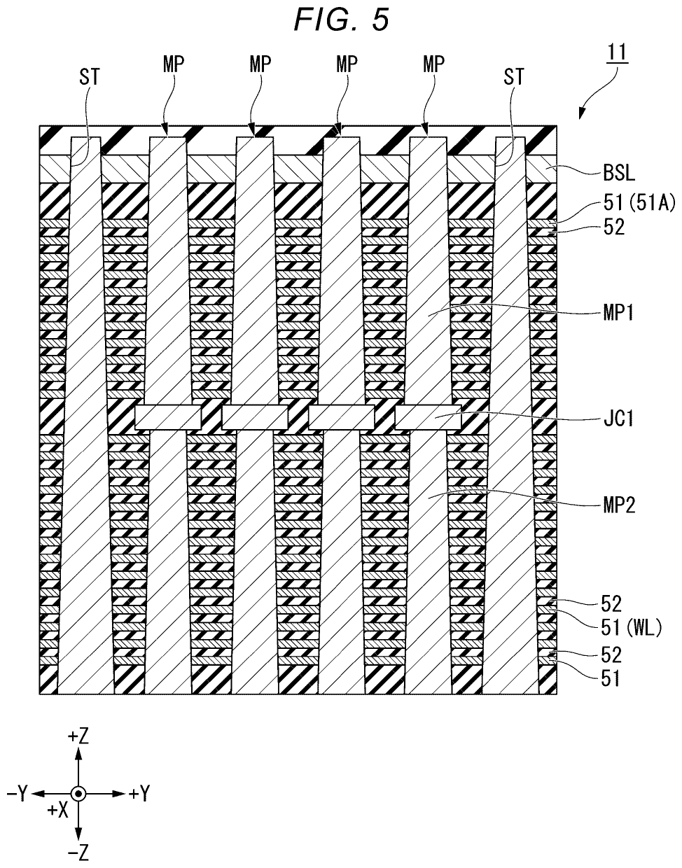

The conductor 30 extends in the Z direction. The configuration of the conductor 30 will be described in detail later. The covering layer 40 is connected to the plurality of conductors 30. The covering layer 40 is, for example, a conductive layer having conductivity. The conductive layer 41 can apply the source voltage from the outside of the semiconductor memory device 1 to a source layer BSL (refer to FIG. 5). The conductive layer 41 is disposed uniformly with respect to the memory cell array 11, and thus a substantially uniform source voltage can be applied to the source layer BSL.

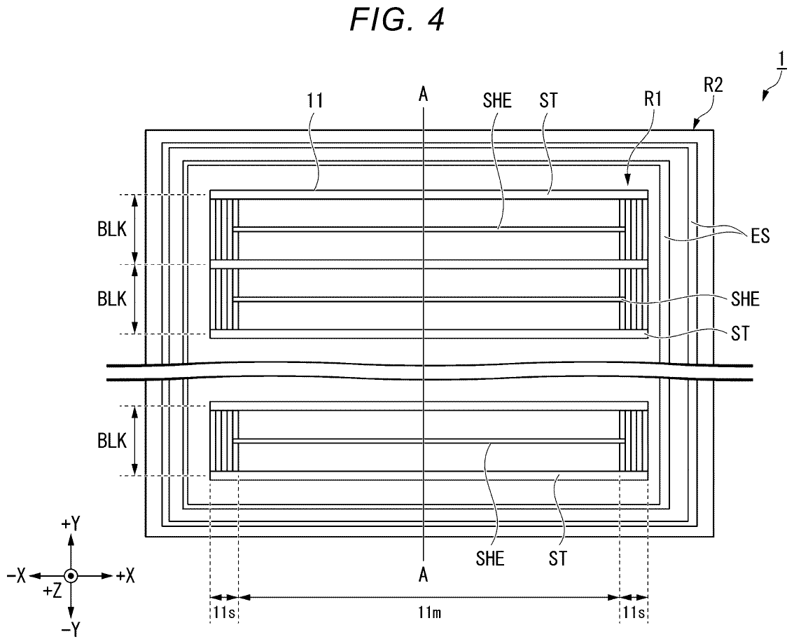

FIG. 4 is a plan view of the semiconductor memory device 1. The semiconductor memory device 1 has a first region R1 and a second region R2 in a plan view from the Z direction. FIG. 3 is a cross section of the semiconductor memory device 1 cut along line A-A of FIG. 4.

The first region R1 is a region overlapping the memory cell array 11 when viewed in a plan view from the Z direction. The first region R1 has the memory cell array 11. The first region R1 has, for example, the first substrate 21, the insulating layer 12, the insulating layer 22, the wiring 15, the wiring 25, the via 16, the via 26, the first pad 23, the second pad 13, the memory cell array 11, the insulating layer 17, the insulating layer 18, the insulating layer 19, and the conductive layer 41. The first region R1 is called a memory cell array region for storing data.

The second region R2 surrounds the first region R1 in the Z direction. The second region R2 has, for example, the first substrate 21, the insulating layer 12, the insulating layer 22, the wiring 15, the wiring 25, the via 16, the via 26, the first pad 23, the second pad 13, the conductor 30, the insulating layer 17, the insulating layer 18, the insulating layer 19, and the covering layer 40.

The second region R2 is called an edge seal region. The second region R2 has one or more edge seals ES. The edge seal ES is formed in a ring shape to surround the first region R1 when viewed in the Z direction. The edge seal ES includes, for example, the wiring 15, the wiring 25, the via 16, the via 26, the first pad 23, the second pad 13, and the conductor 30. The edge seal ES penetrates the insulating layer 12 and the insulating layer 22 in the Z direction. The edge seal ES prevents, for example, moisture from entering the memory cell array 11 from the periphery. The edge seal ES prevents, for example, cracks from being generated toward the memory cell array 11. The edge seal ES contains, for example, a conductive material such as copper or tungsten. The edge seal ES can release or discharge the charges generated during and after the manufacturing to the first substrate 21.

The memory cell array 11 in the first region R1 will be described in detail. As shown in FIG. 4, the memory cell array 11 has a memory cell region 11m and a staircase region 11s. The staircase region 11s is at the edge portion of the memory cell region 11m. The memory cell region 11m is sandwiched between or surrounded by the staircase region 11s.

The memory cell region 11m is divided in the Y direction by the plurality of slits ST and a plurality of slits SHE. Each of the slits ST is formed from the staircase region 11s on the first end side in the X direction of the memory cell array 11 to the staircase region on the second end side via the memory cell region 11m. The slit SHE is formed in at least the memory cell region 11m. The slit SHE is shallower than the slit ST and is formed substantially parallel to the slit ST. The slit SHE electrically separates the conductive layer (i.e., the word line) for each drain-side select gate line SGD. The inside of the slit ST is filled with, for example, a conductor or an insulator. The inside of the slit SHE is filled with, for example, an insulator.

A part of the memory cell array 11 sandwiched between the two slits ST is the block BLK. Each of the blocks BLK corresponds to each of the blocks BLK0 to BLK(k-1) in FIGS. 1 and 2. A part of the memory cell array 11 sandwiched between the slit ST and the slit SHE is called a finger. By dividing the drain-side select gate line SG1 for each finger, a specific finger in the block BLK can be selected by the drain-side select gate line SG1 at the time of data writing and data reading.

FIG. 5 is a cross-sectional view of the memory cell array 11. The memory cell array 11 includes a plurality of conductive layers 51, a plurality of insulating layers 52, the source layer BSL, the plurality of columnar bodies MP, and the slit ST. The conductive layer 51 and the insulating layer 52 are alternately stacked. The source layer BSL contains, for example, a conductive material such as doped polysilicon. The slit ST is filled with a conductive material such as copper or tungsten.

The plurality of conductive layers 51 widen in the X direction and the Y direction, respectively. The conductive layer 51 is, for example, tungsten or polysilicon doped with impurities. The number of the conductive layers 51 is arbitrary. The conductive layer 51 becomes the drain-side select gate line SGD, the word line WL, and the source-side select gate line SGS. Each of the drain-side select gate line SGD, the word line WL, and the source-side select gate line SGS is exposed in the staircase region 11s of the memory cell array 11 and is respectively connected to the contact plug. Here, the conductive layer 51 located at a position farthest from the first substrate 21 among the plurality of conductive layers 51 is referred to as a first conductive layer 51A.

The plurality of insulating layers 52 widen in the X direction and the Y direction, respectively. The insulating layer 52 contains, for example, silicon oxide. The insulating layer 52 is between the conductive layer 51 and the source layer BSL and between the conductive layers 51 adjacent to each other in the Z direction. The insulating layer 52 insulates between the adjacent conductive layers 51. The number of the insulating layers 52 is determined by the number of the conductive layers 51.

The plurality of columnar bodies MP are provided in the memory cell array 11. The columnar bodies MP respectively extend in the Z direction. Each of the columnar bodies MP penetrates, for example, the plurality of conductive layers 51, the plurality of insulating layers 52, and the source layer BSL in the Z direction. The columnar body MP has, for example, a circular or elliptical shape when viewed in a plan view in the Z direction.

The columnar body MP includes, for example, a first columnar body MP1, a second columnar body MP2, and a connection portion JC1.

The first columnar body MP1 is in contact with the source layer BSL. The first columnar body MP1 extends in the Z direction in the memory cell array 11. For example, the first columnar body MP1 has a width in the X direction and a width in the Y direction that gradually increase from an upper end toward a lower end.

The second columnar body MP2 is in contact with the contact plug. The second columnar body MP2 extends in the Z direction in the memory cell array 11. For example, the second columnar body MP2 has a width in the X direction and a width in the Y direction that gradually increase from an upper end toward a lower end.

The connection portion JC1 is positioned between the first columnar body MP1 and the second columnar body MP2. The connection portion JC1 bonds the first columnar body MP1 and the second columnar body MP2. A width of the connection portion JC1 in the X direction and the Y direction is larger than a width of each of the first columnar body MP1 and the second columnar body MP2 in the X direction and the Y direction.

Here, an example in which the columnar body MP has the first columnar body MP1, the second columnar body MP2, and the connection portion JC1 is shown, but the shape of the columnar body MP is not limited to this example. For example, the columnar body MP may be a columnar body that does not have the connection portion JC1 and that communicates in the Z direction. For example, the columnar body MP may have a plurality of connection portions at different positions in the Z direction, and the plurality of columnar bodies may have a shape connected to each other in the Z direction by the connection portions. The shape of the columnar body MP is different depending on the manufacturing step of the memory cell array 11. For example, the columnar body MP including the first columnar body MP1, the second columnar body MP2, and the connection portion JC1 is obtained by forming the memory cell array 11 in two steps for each columnar body.

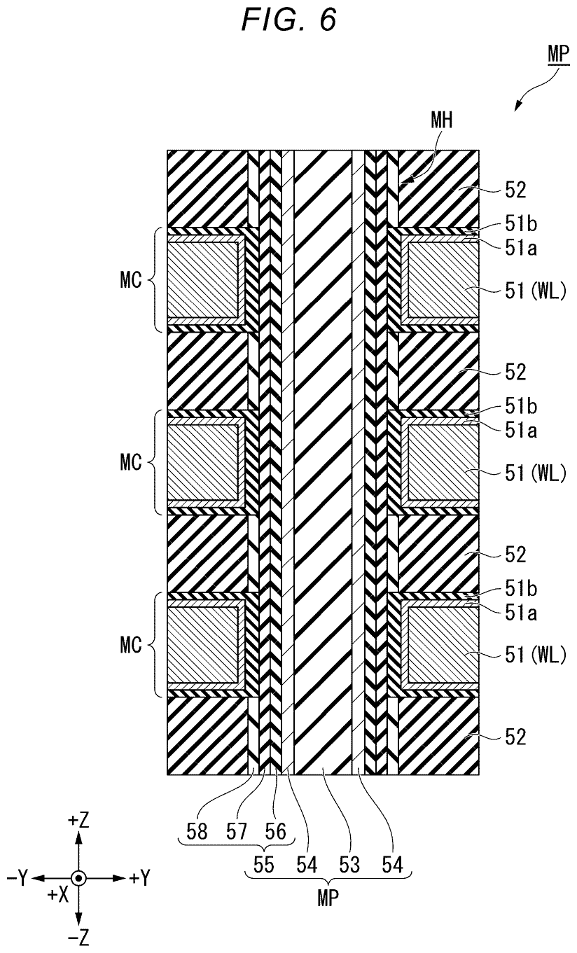

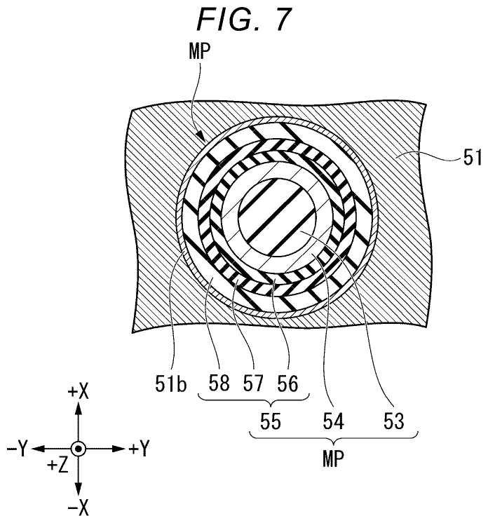

FIG. 6 is a cross-sectional view in the vicinity of the columnar body MP of the memory cell array 11. FIG. 7 is another cross-sectional view in the vicinity of the columnar body MP of the memory cell array 11. FIG. 7 is a cross section in which the columnar body MP is cut along the conductive layer 51.

Each of the columnar bodies MP has a core 53, a semiconductor body 54, and a memory film 55 in order from the inner side. The columnar body MP is formed in a memory hole MH.

The core 53 extends in the Z direction and has a columnar shape. The core 53 contains, for example, a silicon oxide. The core 53 is on the inner side of the semiconductor body 54.

The semiconductor body 54 extends in the Z direction. The semiconductor body 54 is connected to the source layer BSL. The semiconductor body 54 covers an outer side surface of the core 53. The semiconductor body 54 contains, for example, silicon. The silicon is, for example, polysilicon in which amorphous silicon is crystallized.

The memory film 55 extends in the Z direction. The memory film 55 covers the outer side surface of the semiconductor body 54. The memory film 55 is between the inner surface of the memory hole MH and the outer side surface of the semiconductor body 54. The memory film 55 includes, for example, a tunnel insulating film 56 and a charge storage film 57. The tunnel insulating film 56 and the charge storage film 57 are close to the semiconductor body 54 in this order.

The tunnel insulating film 56 is positioned between the charge storage film 57 and the semiconductor body 54. The tunnel insulating film 56 contains, for example, a silicon oxide, or a silicon oxide and a silicon nitride. The tunnel insulating film 56 is a voltage barrier between the semiconductor body 54 and the charge storage film 57.

The charge storage film 57 is positioned between each of the insulating layer 52 and the conductive layer 51 and the tunnel insulating film 56. The charge storage film 57 contains, for example, silicon nitride. A part where the charge storage film 57 intersects each of the plurality of conductive layers 51 functions as a memory cell. The memory cell stores data in accordance with the presence or absence of charges or the amount of charges accumulated within the part (i.e., the charge storage portion) where the charge storage film 57 intersects the plurality of conductive layers 51. The charge storage portion is between each of the conductive layers 51 and the semiconductor body 54 and is surrounded by an insulating material.

A block insulating film 51a and a barrier film 51b may be provided between each of the conductive layers 51 and the insulating layer 52 and between each of the conductive layers 51 and the memory film 55. The block insulating film 51a prevents the back tunneling. The back tunneling is a phenomenon in which charges return from the conductive layer 51 to the memory film 55. The block insulating film 51a is, for example, a silicon oxide film, a metal oxide film, or a stacked structure film in which a plurality of insulating films are stacked. An example of the metal oxide is aluminum oxide. The barrier film 51b is made of, for example, titanium nitride or is a stacked structure film of titanium nitride and titanium.

The columnar body MP may have a cover insulating film 58 between each of the insulating layers 52 and the charge storage film 57. The cover insulating film 58 contains, for example, a silicon oxide. The cover insulating film 58 protects the charge storage film 57 from etching during processing. The cover insulating film 58 may not be provided, or may be used as a block insulating film by leaving a part of the cover insulating film 58 between the conductive layer 51 and the charge storage film 57.

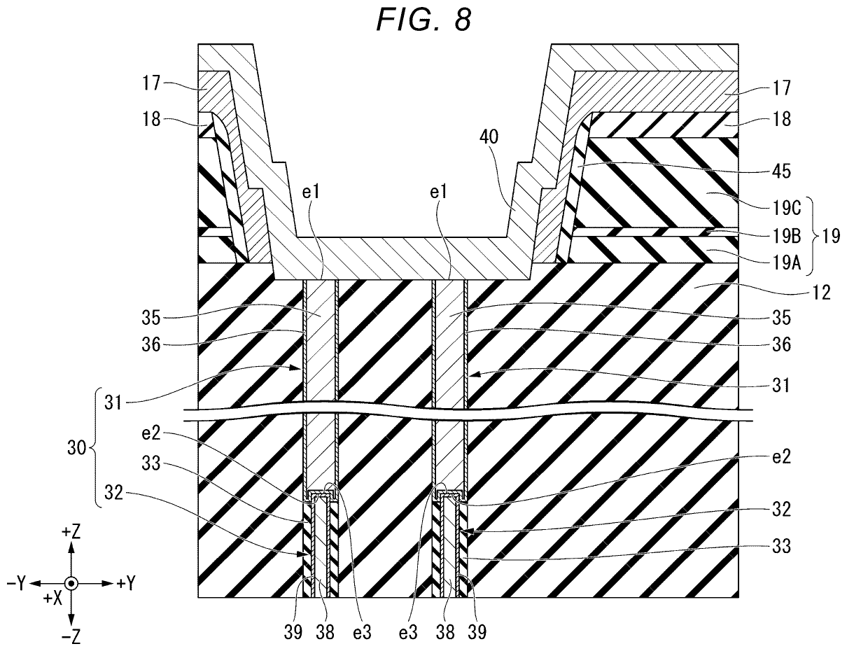

FIG. 8 is a cross-sectional view of a characteristic part of the semiconductor memory device 1. FIG. 8 is a cross-sectional view showing an enlarged vicinity of the conductor 30 in the second region R2.

The conductor 30 extends in the insulating layer 12 of the memory chip 10 in the Z direction. The conductor 30 includes a first conductor 31 and a second conductor 32.

A first end e1 of the first conductor 31 is in contact with the covering layer 40. The first end e1 is an upper end of the first conductor 31. A second end e2 of the first conductor 31 is in contact with the second conductor 32. The second end e2 is an end portion of the first conductor 31 on a side opposite to the first end e1 in the Z direction and a lower end of the first conductor 31. The second end e2 is, for example, located closer to the first substrate 21 than the first conductive layer 51A (refer to FIG. 5). The first conductive layer 51A is the conductive layer 51 located at a position farthest from the first substrate 21 in the memory cell array 11. Further, as shown in FIG. 5, when the columnar body MP has the first columnar body MP1, the connection portion JC1, and the second columnar body MP2, the second end e2 may be located at the same height position as the connection portion JC1.

The first conductor 31 includes a first core 35 and a first barrier metal film 36. The first core 35 contains, for example, a material having conductivity such as copper or tungsten. The first core 35 may contain the same metal as a second core 38 to be described later, or may contain a different material from the second core 38. The first core 35 is freely designed regardless of the material constituting the second core 38 because the first core 35 is formed at a timing different from the second core 38 in the manufacturing process.

The first barrier metal film 36 covers an outer periphery of the first core 35. The first barrier metal film 36 covers, for example, a side surface and a lower surface of the first core 35. The second end e2 of the first conductor 31 is covered with the first barrier metal film 36. The first barrier metal film 36 is made of, for example, titanium nitride or is a stacked structure film of titanium nitride and titanium, or the like. The first barrier metal film 36 enhances adhesion between the first core 35 and the insulating layer 12.

The second conductor 32 includes a second core 38 and a second barrier metal film 39. The periphery of the second conductor 32 may be covered with an insulating film 33. The insulating film 33 is, for example, silicon oxide. The second conductor 32 may contain the same metal as the first conductor 31 or may include a different metal.

The second core 38 contains, for example, a material having conductivity such as copper or tungsten. The second barrier metal film 39 covers an outer periphery of the second core 38. The second barrier metal film 39 covers, for example, a side surface and an upper surface of the second core 38. A first end e3 of the second conductor 32 is covered with the second barrier metal film 39. The first end e3 of the second conductor 32 is an upper end of the second conductor 32. The second barrier metal film 39 is made of, for example, titanium nitride or is a stacked structure film of titanium nitride and titanium, or the like.

The first end e3 of the second conductor 32 is in contact with the second end e2 of the first conductor 31. The second end e2 of the first conductor 31 may be partially recessed in the Z direction with respect to the XY plane. That is, the second end e2 may have different height positions in the Z direction between an outer peripheral part and a central part. The first end e3 of the second conductor 32 may be fitted to the recess (i.e., the central part). The first end e3 of the second conductor 32 may be located at a position farther from the first substrate 21 in the Z direction than at least a part of the second end e2 of the first conductor 31. For example, the first end e3 of the second conductor 32 may be above at least a part of the second end e2 of the first conductor 31. A peripheral length of the second end e2 of the first conductor 31 may be longer than a peripheral length of the first end e3 of the second conductor 32.

The covering layer 40 is connected to, for example, the first end e1 of one or the plurality of conductors 30. The covering layer 40 is formed, for example, in the opening formed in the insulating layer 17, the insulating layer 18, and the insulating layer 19. The insulating layer 19 shown in FIG. 8 has a three-layer structure of a polysilicon layer 19A, a silicon oxide layer 19B, and a polysilicon layer 19C. A protection layer 45 that covers the side surface of the opening may be formed in the opening. The protection layer 45 is, for example, silicon oxide.

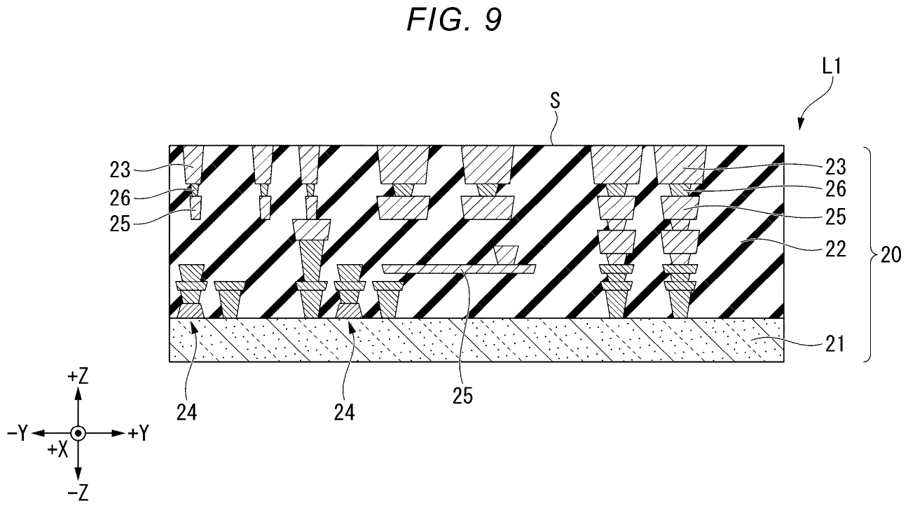

Next, a method for manufacturing the semiconductor memory device 1 will be described. The semiconductor memory device 1 is made by bonding the memory chip 10 and the circuit chip 20 to each other. FIGS. 9 to 20 are cross-sectional views showing the method for manufacturing the semiconductor memory device 1.

The memory chip 10 and the circuit chip 20 are made separately. As shown in FIG. 9, the circuit chip 20 is formed by stacking a first stacked body L1 on the first substrate 21. The first stacked body L1 includes, for example, the first pad 23 and the transistor 24. The periphery of the first pad 23 and the transistor 24 is covered with the insulating layer 22, and the first pad 23 and the transistor 24 are electrically connected to each other through the wiring 25 and the via 26. The first stacked body L1 is formed by repeating the processing of film formation for each layer, photolithography, and the like for each layer. The film forming method and the processing method may use a known method. The plurality of first pads 23 are exposed on the bonding surface S of the circuit chip 20 on the side opposite to the first substrate 21.

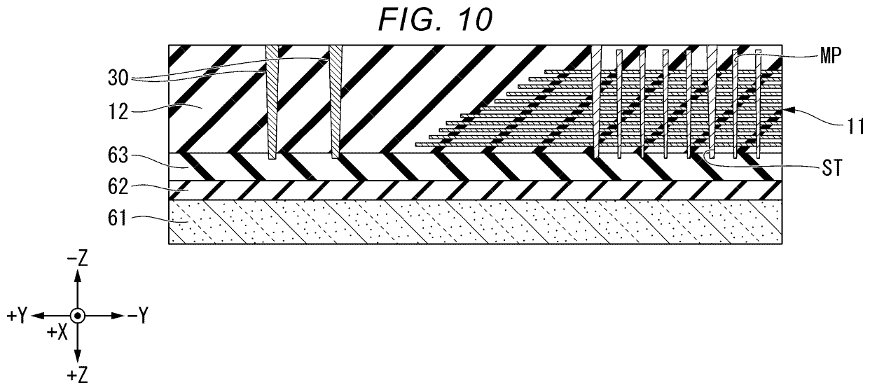

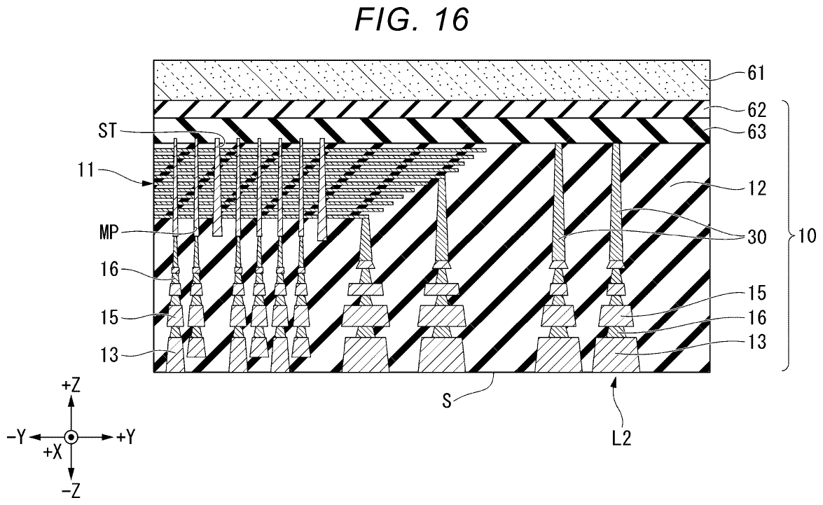

The memory chip 10 is formed by stacking a second stacked body L2 (refer to FIG. 16) on a second substrate 61. A manufacturing process of the second stacked body L2 will be described in detail with reference to FIGS. 10 to 16.

First, as shown in FIG. 10, intermediate layers 62 and 63 are stacked on the second substrate 61. The intermediate layer 62 is a layer that becomes the insulating layer 19, and the intermediate layer 63 is a layer that becomes the insulating layer 18. Next, the conductor 30 and the memory cell array 11 are formed at different positions of the intermediate layer 63. The memory cell array 11 can be formed by performing a step of forming a stacked body in which the insulating layer 52 and the sacrificial layer are alternately stacked, a step of forming the columnar body MP and the slit ST penetrating the stacked body, and a step of replacing the sacrificial layer with the conductive layer 51 via the slit ST.

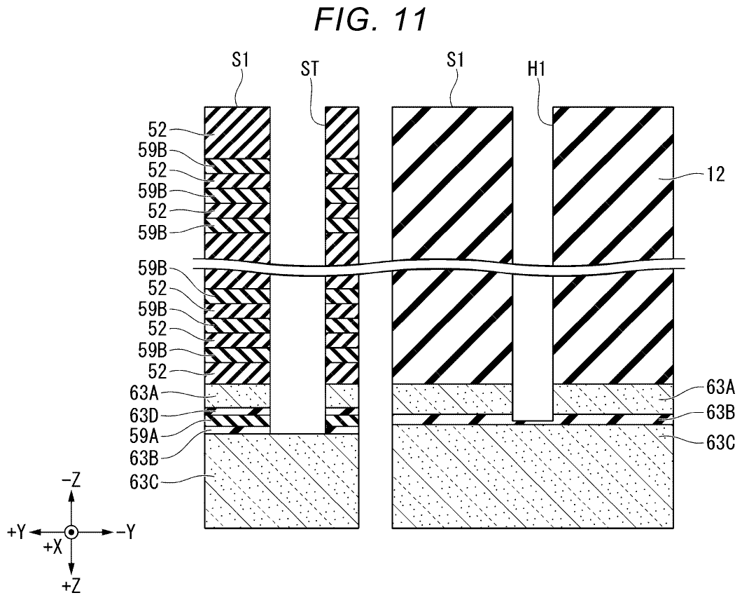

The formation of the conductor 30 will be described in detail below. In FIGS. 11 to 15, the vicinity of the slit ST of the memory cell array 11 and the vicinity of the part where the conductor 30 is formed are correlated with each other and shown. In FIGS. 11 to 15, the left side is an enlarged view in the vicinity of the slit ST, and the right side is an enlarged view in the vicinity of the part where the conductor 30 is formed.

As shown in FIG. 11, the slit ST is formed in a stacked body in which a polysilicon layer 63C, a silicon oxide layer 63B, a sacrificial layer 59A, a silicon oxide layer 63D, a polysilicon layer 63A, the plurality of insulating layers 52, and a plurality of sacrificial layers 59B are stacked. The slit ST reaches from a first surface S1 of the stacked body to the silicon oxide layer 63B.

A first opening H1 for forming the conductor 30 is formed at a position different from the slit ST in the same XY plane. The first opening H1 is formed in the second region R2 that surrounds the first region R1 in which the memory cell array 11 is formed when viewed in the Z direction. In the second region R2, the insulating layer 12 is stacked on the polysilicon layer 63C, the silicon oxide layer 63B, and the polysilicon layer 63A. The first opening H1 penetrates the insulating layer 12 in the Z direction. The first opening H1 reaches from the first surface S1 of the stacked body to the silicon oxide layer 63B.

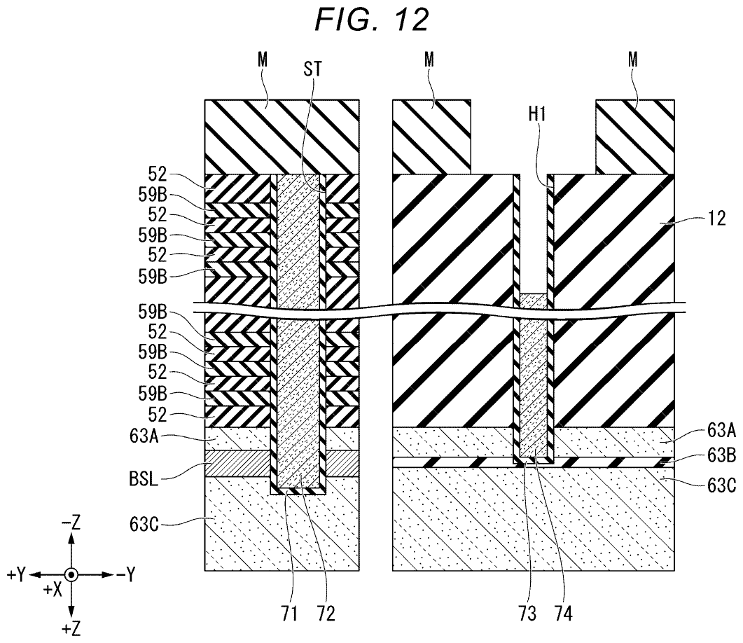

Next, as shown in FIG. 12, the silicon oxide layer 63B, the silicon oxide layer 63D, and the sacrificial layer 59A are dissolved through the slit ST, and then the source layer BSL is formed. The silicon oxide layer 63B in the vicinity of the first opening H1 is not dissolved and remains as it is. Next, a sacrificial layer 74 is formed in the first opening H1. The sacrificial layer 74 is filled after an oxide film 73 is formed on the inner side of the first opening H1. After the material for the sacrificial layer is filled up to the upper surface of the insulating layer 12, the sacrificial layer 74 is obtained by removing a part of the material. The oxide film 71 and the sacrificial layer 72 are formed in the slit ST at the same time as the oxide film 73 and the sacrificial layer 74 are formed. The oxide film 73 and the oxide film 71 are formed by, for example, a chemical vapor deposition (CVD) method, and the sacrificial layer 74 and the sacrificial layer 72 are formed by, for example, the CVD method. The oxide film 71 and the oxide film 73 are, for example, silicon oxide, and the sacrificial layer 72 and the sacrificial layer 74 are amorphous silicon.

The sacrificial layer 74 is specifically obtained by the following procedure. A mask M that covers the upper portion of the slit ST is formed. The mask M is not formed on the first opening H1. A part of the filling material (i.e., amorphous silicon) filled in the first opening H1 is removed through the opening portion of the mask M. By removing a part of the filling material, the sacrificial layer 74 is obtained, which is filled up to the midpoint in the depth direction of the first opening H1.

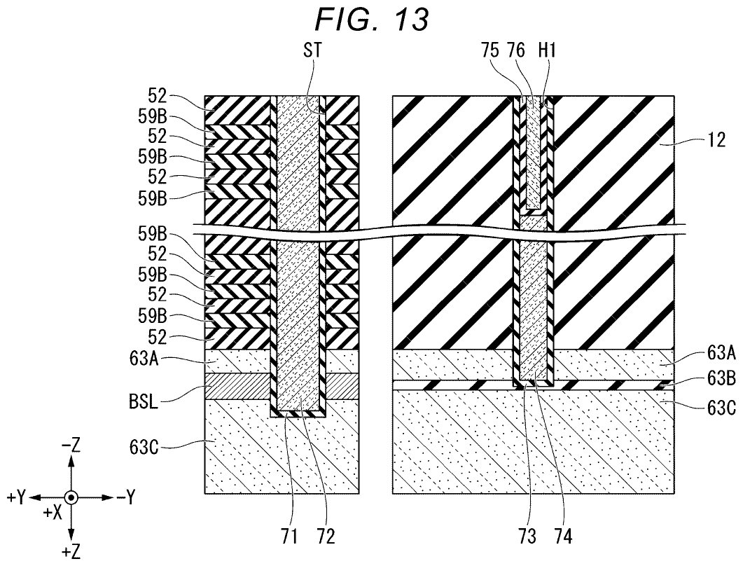

Next, as shown in FIG. 13, a sacrificial layer 76 is further formed on the sacrificial layer 74 on the inner side of the first opening H1. The sacrificial layer 76 is filled after the oxide film 75 is formed on the inner side of the first opening H1. The oxide film 75 is, for example, silicon oxide, and the sacrificial layer 76 is amorphous silicon. Then, the mask M formed on the stacked body is removed.

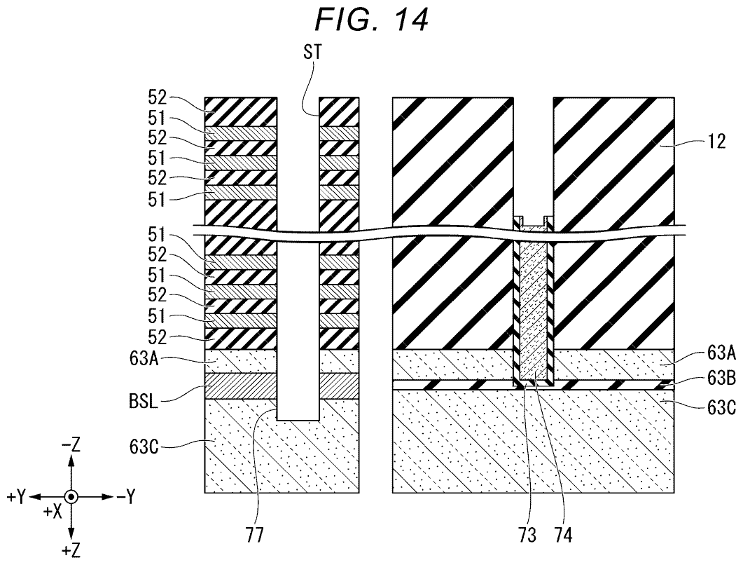

Next, as shown in FIG. 14, the oxide film 75 and the sacrificial layer 76 are removed. In the same step as this step, the oxide film 71 and the sacrificial layer 72 in the slit ST are removed. In addition, each of the sacrificial layers 59B is replaced with the conductive layer 51 via the slit SL.

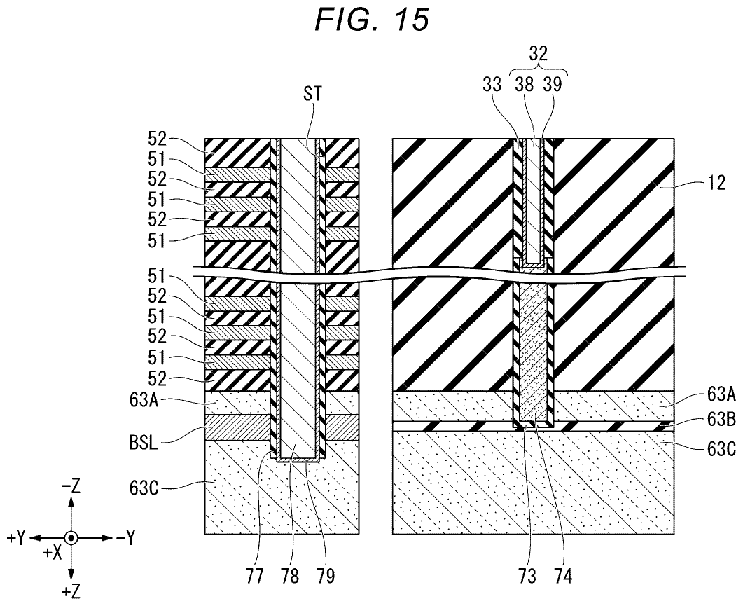

Next, as shown in FIG. 15, an insulating film 77 and a conductor 78 are formed in this order in the slit ST. The insulating film 77 is, for example, silicon oxide. The conductor 78 is, for example, tungsten. A barrier metal film 79 may be provided between the insulating film 77 and the conductor 78. At the same time, the insulating film 33 and the second conductor 32 are formed in this order at the part from which the sacrificial layer 76 is removed. The second conductor 32 has the second core 38 and the second barrier metal film 39. The second conductor 32 reaches the first surface of the sacrificial layer 74.

Next, the second pad 13 electrically connected to the conductor 30 and the columnar body MP of the memory cell array 11 is prepared. The conductor 30 and the memory cell array 11 are electrically connected to the second pad 13 through the wiring 15 and the via 16. The second stacked body L2 is prepared by repeating the processing of film formation for each layer, photolithography, and the like for each layer. The film forming method and the processing method may use a known method. The plurality of second pads 13 are exposed on the bonding surface S on the side opposite to the second substrate 61 of the memory chip 10. Then, as shown in FIG. 16, the second stacked body L2 is inverted upside down.

Next, the first stacked body L1 and the second stacked body L2 are bonded to each other at the bonding surface S such that the first pad 23 and the second pad 13 are connected to each other.

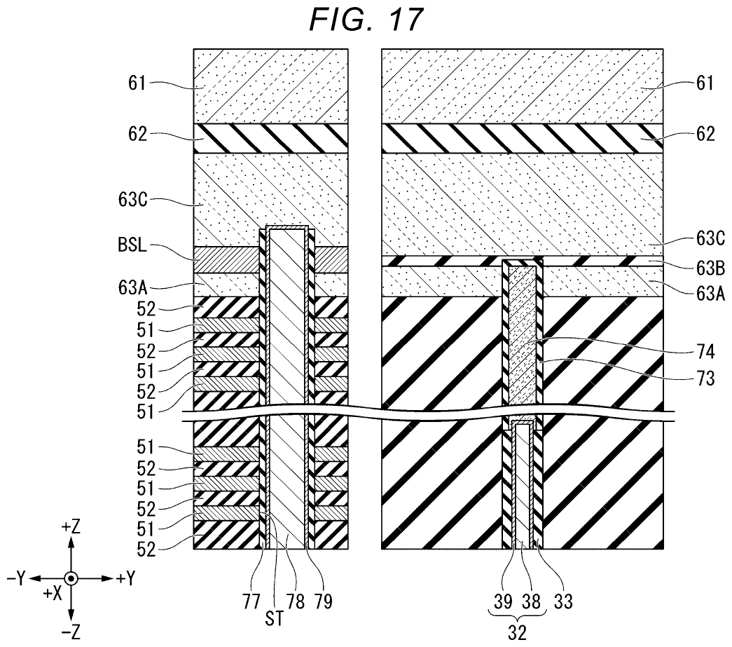

Next, the formation of the conductor 30 will be further described. The formation of the conductor 30 will be described in detail below. In FIGS. 17 to 20, the vicinity of the slit ST of the memory cell array 11 and the vicinity of the part where the conductor 30 is formed are correlated with each other.

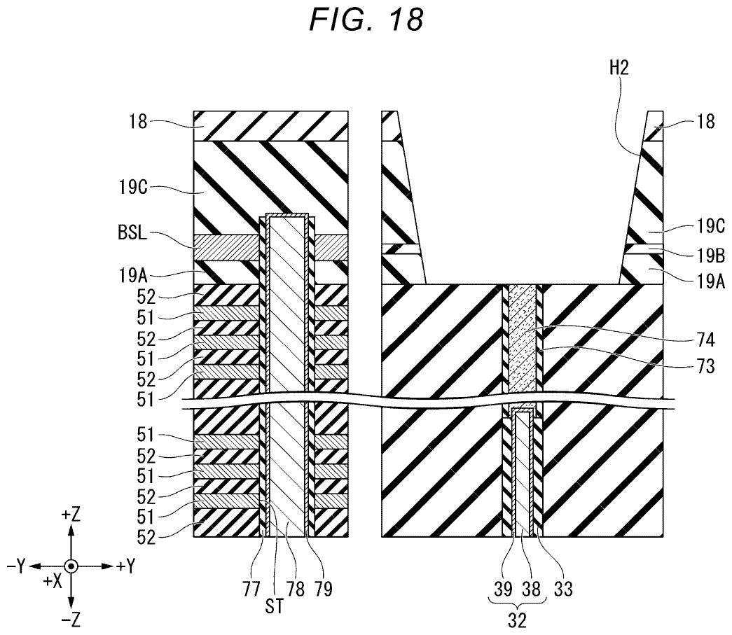

As shown in FIG. 17, the sacrificial layer 74 is above the second conductor 32 by inverting the second stacked body L2 upside down. Next, as shown in FIG. 18, the second substrate 61 is peeled off, and then a second opening H2 that reaches the second surface of the sacrificial layer 74 is formed. By forming the second opening H2, a part of the sacrificial layer 74 is exposed. In addition, by forming the second opening H2, the polysilicon layer 63A becomes the polysilicon layer 19A, the silicon oxide layer 63B becomes the silicon oxide layer 19B, the polysilicon layer 63C becomes the polysilicon layer 19C, and the intermediate layer 62 becomes the insulating layer 18.

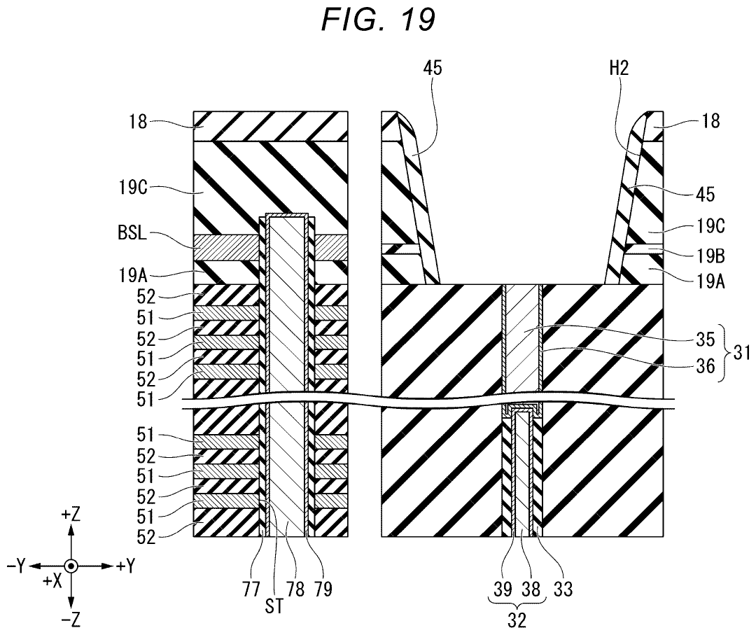

Next, as shown in FIG. 19, the oxide film 73 and the sacrificial layer 74 are removed from the second opening H2. The oxide film 73 and the sacrificial layer 74 are removed from the sacrificial layer 72 and the sacrificial layer 74 formed in the slit ST in different steps, respectively. Next, the first barrier metal film 36 and the first core 35 are sequentially stacked on the part from which the oxide film 73 and the sacrificial layer 74 are removed to form the first conductor 31. Since the first conductor 31 is formed at a timing different from the second conductor 32, the material constituting the first conductor 31 can be freely set regardless of the material constituting the second conductor 32. In addition, the protection layer 45 that covers the side surface of the second opening H2 is formed in the second opening H2.

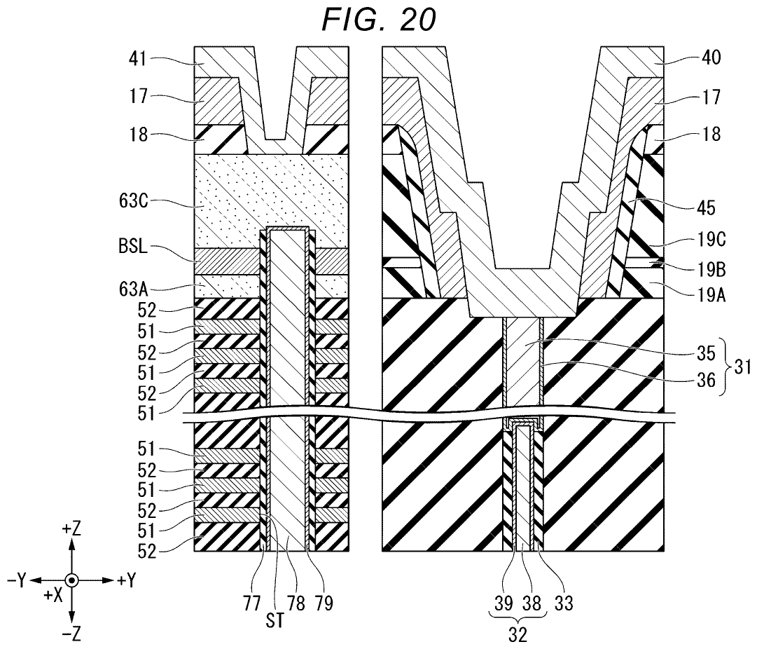

Next, in FIG. 20, the insulating layer 17 is stacked to cover the second opening H2 and the protection layer 45. Next, an opening is formed at a part of the insulating layer 17 overlapping the first conductor 31 when viewed in the Z direction, and the covering layer 40 is formed. The covering layer 40 is connected to the first conductor 31. In addition, the conductive layer 41 is formed on the upper portion of the slit ST. The semiconductor memory device 1 is made by the above steps. The manufacturing steps shown here is an example, and other steps may be inserted between each of the steps.

The conductor 30 has a length in the Z direction that is longer than the widths in the X direction and the Y direction and has a large aspect ratio in the Z direction. When the conductor 30 having such a high aspect ratio structure is formed at once, the conductor 30 may be inclined from the Z direction. When the conductor 30 is inclined, a gap may be generated in a connection portion between the contact plug and the conductor 30. That is, a gap formed of a material other than metal is formed at a part of the edge seal ES extending in the Z direction. The gap may be a path for moisture and cracks to enter, and may be a cause of deterioration in reliability of the semiconductor memory device 1. In contrast, in the method for manufacturing the semiconductor memory device 1 described above, the conductor 30 having a high aspect ratio structure is formed in two steps. Therefore, even the conductor 30 having a high aspect ratio structure can be prevented from being inclined in the manufacturing process. When the conductor 30 is not inclined, a gap is not generated in the connection portion between the conductor 30 and the contact plug, and a highly reliable semiconductor memory device 1 is obtained.

### Second Embodiment

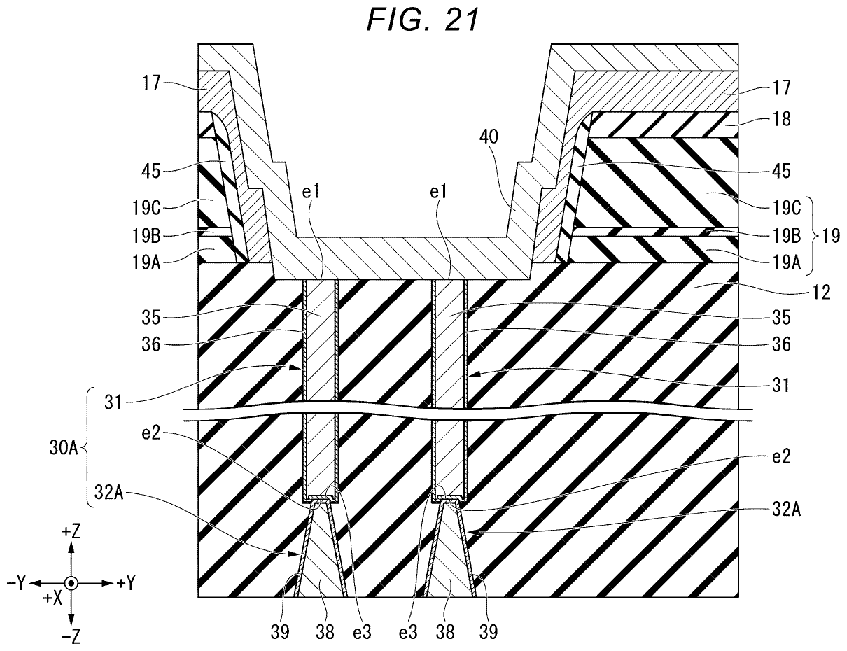

FIG. 21 is a cross-sectional view of a semiconductor memory device according to a second embodiment. FIG. 21 is a cross-sectional view showing an enlarged vicinity of a conductor 30A in the second region R2 of the semiconductor memory device according to the second embodiment. Here, the shape of the conductor 30A is different from the shape of the conductor 30. In the semiconductor memory device according to the second embodiment, the same configuration as the semiconductor memory device 1 according to the first embodiment is denoted by the same reference numerals, and the description thereof is omitted.

The conductor 30A extends in the Z direction in the insulating layer 12 of the memory chip 10. The conductor 30A includes a first conductor 31A and a second conductor 32A. The first conductor 31A differs from the first conductor 31 according to the first embodiment only in the shape thereof, and other configurations are similar to those of the first conductor 31. The second conductor 32A differs from the second conductor 32 according to the first embodiment only in the shape thereof, and other configurations are similar to those of the second conductor 32.

The first end e1 of the first conductor 31A is in contact with the covering layer 40. The first end e1 is an upper end of the first conductor 31A. The second end e2 of the first conductor 31A is in contact with the second conductor 32A. The second end e2 is, for example, located closer to the first substrate 21 than the first conductive layer 51A (refer to FIG. 5). The first conductive layer 51A is the conductive layer 51 located at a position farthest from the first substrate 21 in the memory cell array 11.

The first end e3 of the second conductor 32A is in contact with the second end e2 of the first conductor 31A. The second end e2 of the first conductor 31A may be partially recessed in the Z direction with respect to the XY plane. The first end e3 of the second conductor 32A may be fitted to the recess (i.e., the central part). The first end e3 of the second conductor 32A may be located at a position farther from the first substrate 21 in the Z direction than at least a part of the second end e2 of the first conductor 31A. For example, the first end e3 of the second conductor 32A may be above at least a part of the second end e2 of the first conductor 31A. A peripheral length of the second end e2 of the first conductor 31A may be longer than a peripheral length of the first end e3 of the second conductor 32A. The peripheral length of the second conductor 32A may be longer as it is farther from the first end e3. For example, the width of the second conductor 32A may be wider as it is farther from the first end e3.

Next, a method for manufacturing the semiconductor memory device according to the second embodiment will be described. In the method for manufacturing the semiconductor memory device according to the second embodiment, the point of forming the memory chip 10 and the circuit chip 20 separately is the same as the method for manufacturing the semiconductor memory device 1 according to the first embodiment. The method for manufacturing the circuit chip 20 is the same as the method for manufacturing the semiconductor memory device 1 according to the first embodiment, and the description thereof will be omitted.

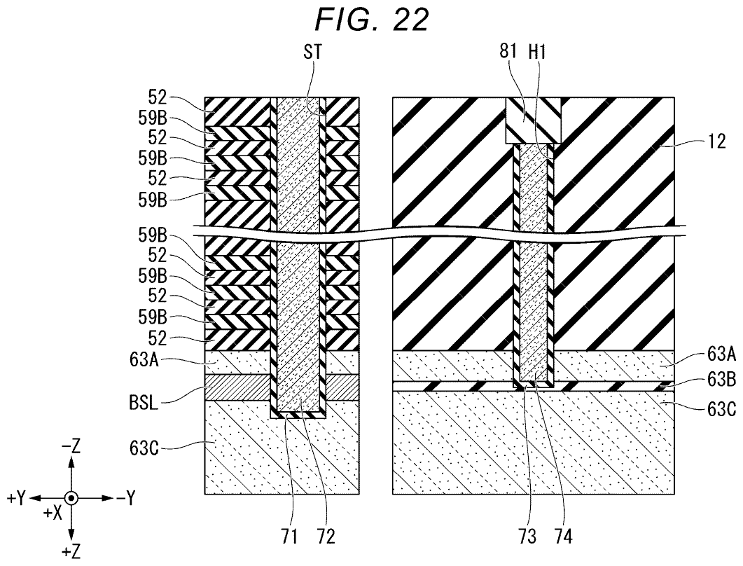

Next, a method for manufacturing the memory chip 10 will be described. In the method for manufacturing the semiconductor memory device according to the second embodiment, the method for manufacturing the memory cell array 11 and the like of the memory chip 10 is the same as that of the semiconductor memory device 1 according to the first embodiment. In the method for manufacturing the semiconductor memory device according to the second embodiment, the method for manufacturing the conductor 30A is different from the method for manufacturing the conductor 30 according to the first embodiment. This point will be described in detail with reference to FIGS. 22 to 27. In FIGS. 22 to 27, the vicinity of the slit ST of the memory cell array 11 and the vicinity of the part where the conductor 30A is formed are correlated with each other. In FIGS. 22 to 27, the left side is an enlarged view in the vicinity of the slit ST, and the right side is an enlarged view in the vicinity of the part where the conductor 30A is formed.

The first opening H1 for forming the conductor 30A is formed at a position different from the slit ST in the same plane. The first opening H1 is formed in the second region R2 that surrounds the first region R1 in which the memory cell array 11 is formed when viewed in the Z direction. In the second region R2, the insulating layer 12 is stacked on the polysilicon layer 63C, the silicon oxide layer 63B, and the polysilicon layer 63A. The first opening H1 penetrates the insulating layer 12 in the Z direction. The first opening H1 reaches from the first surface S1 of the stacked body to the silicon oxide layer 63B.

As shown in FIG. 22, the sacrificial layer 74 is filled in the first opening H1. The sacrificial layer 74 is filled after an oxide film 73 is formed on the inner side of the first opening H1. The sacrificial layer 74 is filled up to the midpoint in the depth direction of the first opening H1. A protection layer 81 is formed on the sacrificial layer 74 on the inner side of the first opening H1. The protection layer 81 is, for example, silicon oxide.

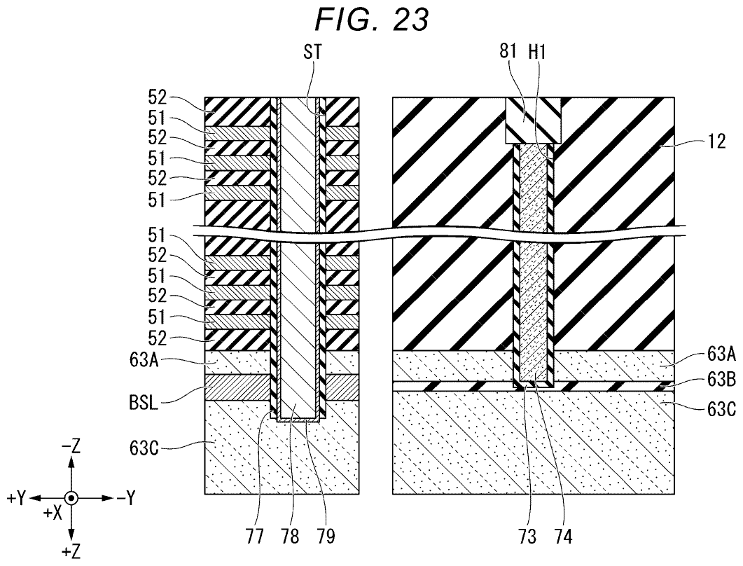

Next, as shown in FIG. 23, the oxide film 71 and the sacrificial layer 72 in the slit ST are removed. Each of the sacrificial layers 59B is replaced with the conductive layer 51 via the slit SL. The sacrificial layer 74 in the first opening H1 is not removed in the same step as the step of removing the sacrificial layer 72 of the slit ST because the sacrificial layer 74 is protected by the protection layer 81. The insulating film 77 and the conductor 78 are sequentially formed in the slit ST from which the oxide film 71 and the sacrificial layer 72 are removed. The barrier metal film 79 may be formed between the insulating film 77 and the conductor 78.

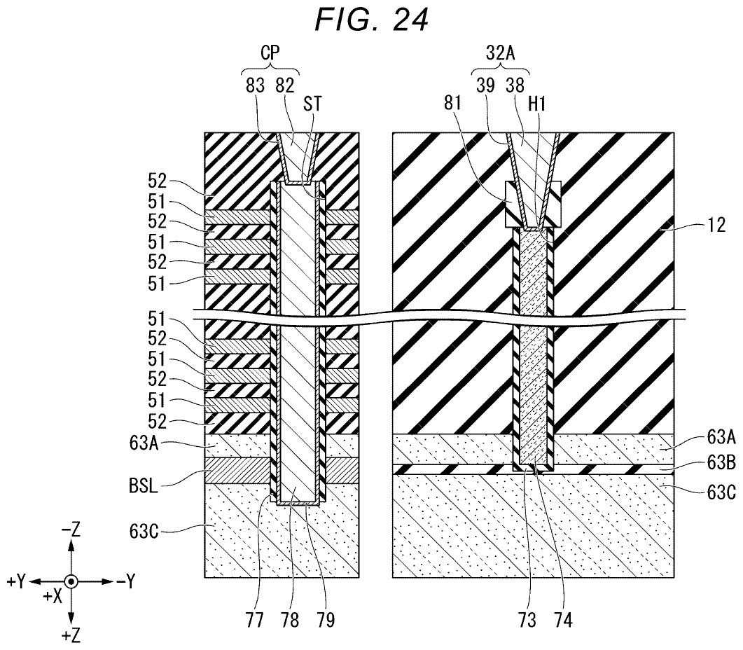

Next, as shown in FIG. 24, the contact plug CP that reaches the conductor 78 in the slit ST is formed. The contact plug CP has a core 82 and a barrier metal film 83. The core 82 is made of a conductive material such as copper or tungsten, and the barrier metal film 83 is made of, for example, titanium nitride or is a stacked structure film of titanium nitride and titanium, or the like. In addition, in the same step as that for forming a contact plug CH, the second conductor 32A that reaches the first surface of the sacrificial layer 74 is formed. The second conductor 32A penetrates the protection layer 81 and reaches the first surface of the sacrificial layer 74. The second conductor 32A has the second core 38 and the second barrier metal film 39.

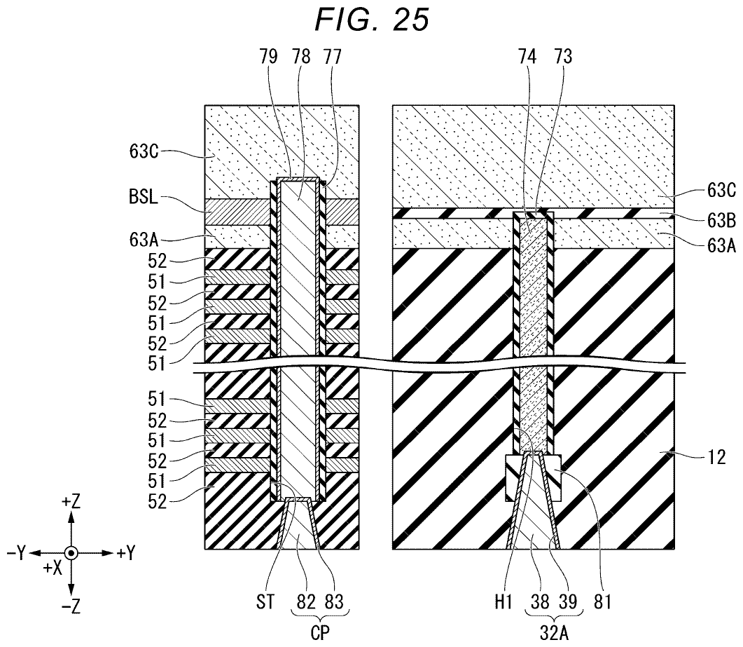

Next, the first stacked body L1 and the second stacked body L2 are bonded to each other at the bonding surface S such that the first pad 23 and the second pad 13 are connected to each other in the same manner as in the method for manufacturing the semiconductor memory device 1 according to the first embodiment. FIG. 25 is a view in which FIG. 24 is inverted upside down. By inverting the second stacked body L2 upside down, the sacrificial layer 74 is above the second conductor 32A.

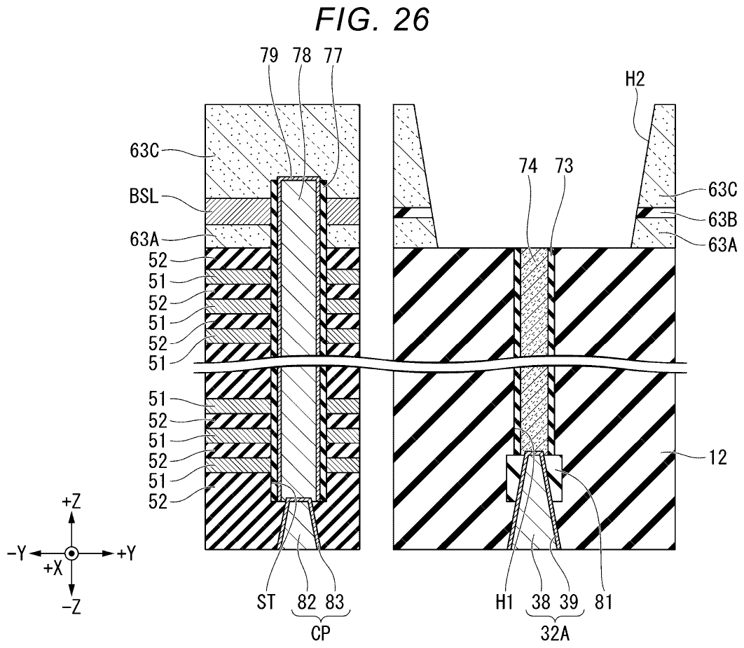

Next, as shown in FIG. 26, the second opening H2 that reaches the second surface of the sacrificial layer 74 is formed. By forming the second opening H2, a part of the sacrificial layer 74 is exposed.

Next, the oxide film 73 and the sacrificial layer 74 are removed from the second opening H2. The first barrier metal film 36 and the first core 35 are sequentially stacked on the part from which the oxide film 73 and the sacrificial layer 74 are removed to form the first conductor 31A. Since the first conductor 31A is formed at a timing different from the second conductor 32A, the material constituting the first conductor 31A can be freely set regardless of the material constituting the second conductor 32A.

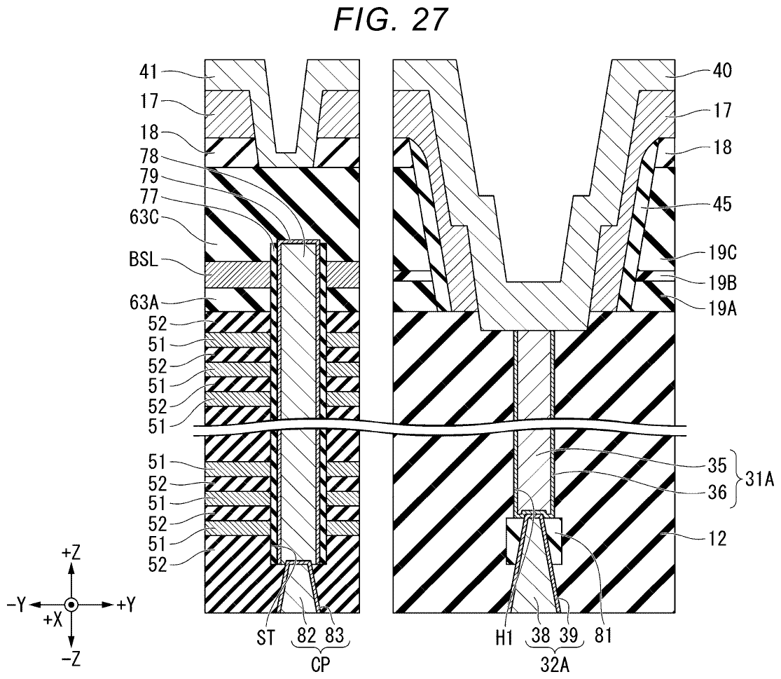

Next, as shown in FIG. 27, the protection layer 45, the insulating layer 17, and the covering layer 40 are formed in the same manner as in the method for manufacturing the semiconductor memory device 1 according to the first embodiment. The covering layer 40 is connected to the first conductor 31A. In addition, the conductive layer 41 is formed on the upper portion of the slit ST. The semiconductor memory device according to the second embodiment is made by the above steps. The manufacturing steps shown here is an example, and other steps may be inserted between each of the steps.

In the method for manufacturing the semiconductor memory device according to the second embodiment, the conductor 30A having a high aspect ratio structure is prepared in two steps. The conductor 30A having a high aspect ratio structure can be prevented from being inclined in the manufacturing process. In the semiconductor memory device according to the second embodiment, the second conductor 32A is formed in the same step as the contact plug CH. Therefore, it is difficult to make the length of the second conductor 32A in the Z direction longer than that of the second conductor 32 of the semiconductor memory device 1 according to the first embodiment. Therefore, the aspect ratio of the first conductor 31A in the Z direction may increase, and the first conductor 31A may be inclined with respect to the Z direction. Even in this case, since the coverage range of the covering layer 40 in the X and Y directions is sufficiently wide with respect to the area of the upper end of the first conductor 31A, no gap is generated between the covering layer 40 and the first conductor 31A even when the first conductor 31A is inclined in the Z direction. The gap becomes a path for moisture and cracks to enter, but when the gap is not formed, deterioration in reliability of the semiconductor memory device can be sufficiently prevented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a substrate including a first region and a second region surrounding the first region when viewed from above the substrate;
an insulating layer on the substrate;
a memory cell array having a plurality of memory cells above the first region;
a conductor above the second region, that extends through the insulating layer in a first direction perpendicular to the substrate; and
a covering layer in contact with the conductor in the first direction, wherein the conductor includes:
a first conductor portion, a first end of which is in contact with the covering layer, and
a second conductor portion in contact with a second end of the first conductor portion that is opposite to the first end in the first direction, and
the first conductor portion includes a first core and a first barrier metal film that covers a side surface of the first core and the second end of the first conductor portion.

2. The semiconductor memory device according to claim 1, wherein
a perimeter of the second end of the first conductor portion is longer than a perimeter of an end of the second conductor portion that is in contact with the second end of the first conductor portion.

3. The semiconductor memory device according to claim 1, wherein
a part of the second conductor portion that is in contact with the first conductor portion is located at a position farther from the substrate in the first direction than a tip of the second end of the first conductor portion.

4. The semiconductor memory device according to claim 3, wherein
the first conductor portion has a recess, an edge of which forms the tip of the second end of the first conductor portion.

5. The semiconductor memory device according to claim 1, wherein
the first conductor portion contains the same metal as the second conductor portion.

6. The semiconductor memory device according to claim 1, wherein
the first conductor portion contains a metal different from a metal contained in the second conductor portion.

7. The semiconductor memory device according to claim 1, wherein
the memory cell array includes a stacked body that has a plurality of conductive layers and a plurality of insulating layers, and
the second end of the first conductor portion is closer to the substrate in the first direction than one of the conductive layers located farthest from the substrate in the first direction.

8. The semiconductor memory device according to claim 1, wherein
the memory cell array includes:
a stacked body that has a plurality of conductive layers and a plurality of insulating layers, and
a columnar body that extends through the stacked body in the first direction,
the columnar body includes a first columnar body that extends in the first direction, a second columnar body that extends in the first direction, and a connection portion between the first and second columnar bodies, and
a distance between the substrate and the second end of the first conductor portion in the first direction is the same as a distance between the substrate and a part of the connection portion in the first direction.

9. The semiconductor memory device according to claim 1, wherein
the second conductor portion includes a second core and a second barrier metal film that covers a side surface of the second core and an end of the second conductor portion that is in contact with the first conductor portion.

10. The semiconductor memory device according to claim 9, wherein
the first barrier metal film contains the same metal as the second barrier metal film.

11. A semiconductor memory device comprising:
a memory chip including a memory cell array; and
a circuit chip on the memory chip and including a sequencer configured to control the memory cell array, wherein the memory chip includes a first region and a second region surrounding the first region when viewed from above,
the memory chip includes the memory cell array in the first region,
the memory chip includes, in the second region:
a conductor that extends in a first direction along which the memory chip and the circuit chip are stacked, and
a covering layer in contact with the conductor in the first direction,
the conductor includes:
a first conductor portion, a first end of which is in contact with the covering layer, and
a second conductor portion in contact with a second end of the first conductor portion that is opposite to the first end in the first direction, and
the first conductor portion includes a first core and a first barrier metal film that covers a side surface of the first core and the second end of the first conductor portion.

12. The semiconductor memory device according to claim 11, wherein
a perimeter of the second end of the first conductor portion is longer than a perimeter of an end of the second conductor portion that is in contact with the second end of the first conductor portion.

13. The semiconductor memory device according to claim 11, wherein
a portion of the second conductor portion that is in contact with the first conductor portion is located at a position farther from the circuit chip in the first direction than a tip of the second end of the first conductor portion.

14. The semiconductor memory device according to claim 13, wherein
the first conductor portion has a recess, an edge of which forms the tip of the second end of the first conductor portion.

15. A method for manufacturing a semiconductor memory device, the method comprising:
forming, on a first substrate, a first stacked body that has a transistor and a first pad electrically connected to the transistor;
forming, on a second substrate, a second stacked body that has a memory cell array in a first region, an insulating layer that covers the memory cell array, and a second pad connected to the memory cell array;
forming a first opening that penetrates the insulating layer in a first direction in a second region that surrounds the first region when viewed in the first direction;
forming a first sacrificial layer in the first opening;
forming a conductor that reaches a first surface of the first sacrificial layer in the first opening;
bonding the first stacked body and the second stacked body to each other to connect the first pad and the second pad to each other;
peeling the second substrate from the second stacked body and forming a second opening that reaches a second surface of the first sacrificial layer that is opposite to the first surface; and
removing the first sacrificial layer that is exposed through the second opening and sequentially stacking a first barrier metal film and a first core at a location where the first sacrificial layer has been removed.

16. The method according to claim 15, wherein
the first sacrificial layer is filled up to a midpoint in a depth direction of the first opening.

17. The method according to claim 15, further comprising:
further forming a second sacrificial layer on the first surface of the first sacrificial layer in the first opening, wherein the conductor that reaches the first surface of the first sacrificial layer is formed at a location where the second sacrificial layer has been removed.

18. The method according to claim 15, further comprising:
further forming a protection layer on the first surface of the first sacrificial layer in the first opening; and
the conductor is formed to penetrate the protection layer and reach the first surface of the first sacrificial layer.

19. The method according to claim 15, further comprising:
forming a slit that penetrates the memory cell array in the first direction;
forming a third sacrificial layer in the slit; and
removing the third sacrificial layer separately from the first sacrificial layer.

20. The method according to claim 15, further comprising:
further forming a second sacrificial layer on the first surface of the first sacrificial layer in the first opening;
forming a slit that penetrates the memory cell array in the first direction;
forming a third sacrificial layer in the slit; and
removing the second sacrificial layer and the third sacrificial layer.
